(19) United States
(12) Patent Application Publication
(10) Pub. No.: US 2010/0259752 A1
(43) Pub. Date: Oct. 14, 2010

(54) SENSORS WITH FIBER BRAGG GRATINGS AND CARBON NANOTUBES

(75) Inventors: Tushar K. Shah, Columbia, MD (US); John J. Morber, Taneytown, MD (US); Pierre Kabro, Perry Hall, MD (US); Sanjay Gupta, La Jolla, CA (US)

Correspondence Address: MCDERMOTT WILL & EMERY LLP, 18191 VON KARMAN AVE., SUITE 500, IRVINE, CA, 92612-7108, US

(73) Assignee: LOCKHEED MARTIN CORPORATION, Bethesda, MD (US)

(21) Appl. No.: 12/758,673

(22) Filed: Apr. 12, 2010

Related U.S. Application Data
(60) Provisional application No. 61/169,063, filed on Apr. 14, 2009.

(51) Int. Cl. G01J 3/00; H01L 31/0232; G02B 6/00

(52) U.S. Cl. 356/300; 250/227.18; 385/12; 977/742; 977/954; 977/957

(57) ABSTRACT

Systems and methods for sensing an external measurand are disclosed. A sensor includes an optical fiber having at least one fiber Bragg grating (FBG) section and a plurality of carbon nanotubes (CNTs) surrounding at least a portion of the FBG section. Light is provided into the sensor while the CNTs are exposed to one or more measurands. A change in a spectrum of one of a transmitted portion and a reflected portion of the light is determined. A measurand that has caused the change is identified.

### CROSS-REFERENCE TO RELATED APPLICATION

The present application claims the benefit of U.S. Provisional Patent Application Ser. No. 61/169,063, entitled “SENSORS COMPRISING FIBER BRAGG GRATINGS AND CARBON NANOTUBES” filed on Apr. 14, 2009, which is hereby incorporated by reference in its entirety for all purposes.

### STATEMENT REGARDING FEDERALLY SPONSORED RESEARCH OR DEVELOPMENT

Not applicable.

### FIELD

The subject technology relates generally to sensors, and more specifically to sensors with fiber Bragg gratings and carbon nanotubes.

### BACKGROUND

A fiber Bragg grating (“FBG”) is a type of distributed Bragg reflector constructed in a short segment of an optical fiber. FIG. 1 is a diagram depicting a conventional FBG 100. The FBG 100 includes a fiber core 110, and a fiber outer cladding 120. The fiber core 110 includes an FBG section. The FBG section 112 reflects or rejects a particular wavelength (“Bragg wavelength”) of input light 101 and transmits all others. Therefore, output (e.g., transmitted) light 103 includes all spectral components of the input light 101 except for the Bragg wavelength associated with the reflected/rejected light portion 130. The FBG section 112 can be typically implemented by adding a periodic variation to the refractive index of the fiber core 110, which generates a wavelength specific dielectric mirror. An FBG 100 can be used as an inline optical filter to block certain wavelengths, or as a wavelength-specific reflector.

### SUMMARY

The present disclosure describes improved FBG sensors that incorporate carbon nanotubes.

In one aspect of the present disclosure, a sensor is provided. The sensor comprises an optical fiber having a radial direction and an axial direction, the optical fiber configured to transmit light along the axial direction and comprising a fiber Bragg grating (FBG) section. The sensor can further comprise a plurality of carbon nanotubes (CNTs) surrounding at least a portion of the FBG section, the CNTs, when exposed to an external measurand, are configured to cause a change in a spectral response of the FBG section.

In one aspect of the present disclosure, a method of sensing an external measurand is provided. The method can comprise providing a sensor comprising an optical fiber, the optical fiber having at least one fiber Bragg grating (FBG) section and a plurality of carbon nanotubes (CNTs) surrounding at least a portion of the FBG section. The method can further comprise providing light to the optical fiber while the CNTs are exposed to one or more measurands. The method can further comprise determining a change in a spectrum of one of a transmitted portion and a reflected portion of the light. The method can further comprise identifying a measurand that has caused the change.

In one aspect of the present disclosure, a method of sensing an external measurand is provided. The method can comprise providing a sensor comprising an optical fiber, the optical fiber having a fiber Bragg grating (FBG) section and a plurality of carbon nanotubes (CNTs) surrounding at least a portion of the at least FBG. The method can further comprise providing light into the sensor while the CNTs are exposed to one or more measurands, the light having a wavelength bandwidth narrower than a range of wavelengths of interest. The method can further comprise sweeping the wavelength bandwidth of the light until a portion of the light is detected at a particular wavelength bandwidth. The method can further comprise determining a change in a spectrum of the detected portion. The method can further comprise identifying a measurand that has caused the change.

### BRIEF DESCRIPTION OF THE DRAWINGS

The accompanying drawings, which are included to provide further understanding of the invention and are incorporated in and constitute a part of this specification, illustrate embodiments of the invention and together with the description serve to explain the principles of the invention.

FIG. 1 is a diagram depicting a conventional FBG structure.

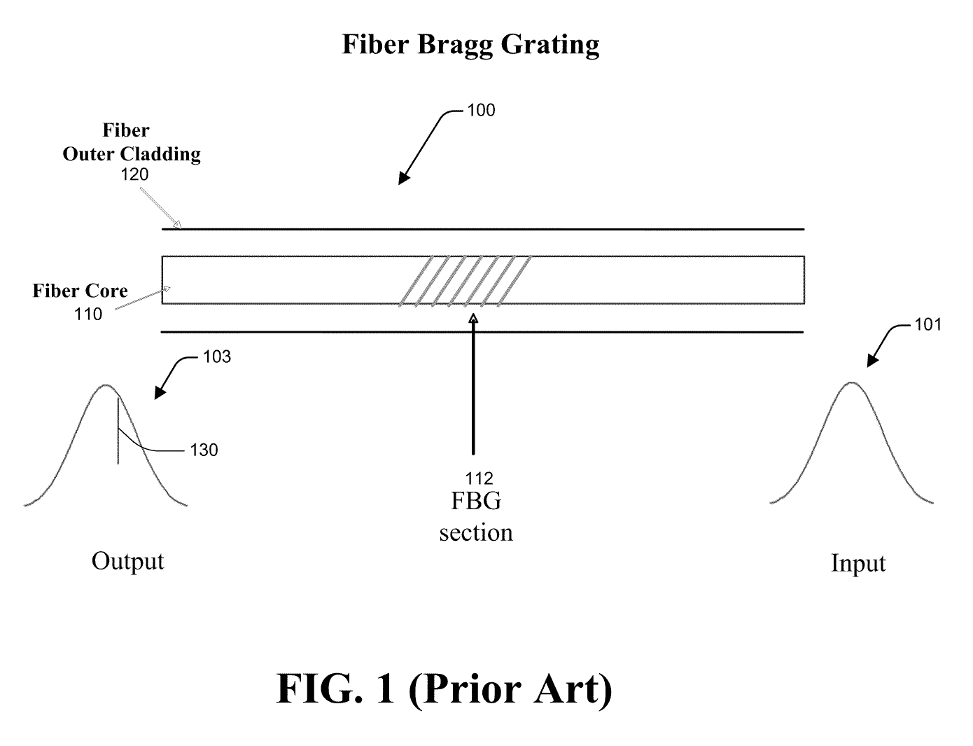

FIG. 2 is a diagram depicting an exemplary FBG sensor having carbon nanotubes (CNTs) as sensing elements according to certain aspects of the present disclosure.

FIG. 3 is a diagram depicting an exemplary sensing system comprising an FBG sensor having multiple CNT-infused FBGs according to certain aspects of the present disclosure.

FIG. 4 depicts a flowchart illustrating an exemplary process for producing CNT-infused glass fiber material, whereby CNT-infused FBGs can be fabricated according to certain aspects of the present disclosure.

FIG. 5A is a schematic block diagram of an exemplary transmission (reject)-type sensing system that is configured to monitor and detect a measurand based on a transmitted portion of the input light according to certain aspects of the present disclosure.

FIG. 5B is a schematic block diagram of an exemplary reflection (accept)-type sensing system that is configured to monitor and detect a measurand based on a reflected portion of the input light according to certain aspects of the present disclosure.

FIG. 6 is a flowchart illustrating an exemplary process for monitoring and detecting one or more measurands by the use of a CNT-bearing FBG sensor according to certain aspects of the present disclosure.

FIG. 7 is a flowchart illustrating an exemplary process for monitoring and detecting one or more measurands by the use of a CNT-bearing FBG sensor according to alternative aspects of the present disclosure.

### DETAILED DESCRIPTION

In the following detailed description, numerous specific details are set forth to provide a full understanding of the disclosed and claimed embodiments. It will be apparent, however, to one ordinarily skilled in the art that the embodiments may be practiced without some of these specific details. In other instances, well-known structures and techniques have not been shown in detail to avoid unnecessarily obscuring the disclosure. The word “exemplary” is used herein to mean “serving as an example, instance, or illustration.” Any embodiment or design described herein as “exemplary” is not necessarily to be construed as preferred or advantageous over other embodiments or designs.

It is to be understood that the disclosure teaches just one example of the illustrative embodiment and that many variations of the invention can easily be devised by those skilled in the art after reading this disclosure and that the scope of the present invention is to be determined by the claims of the application.

A spectral response of an FBG as determined from features (e.g., a Bragg wavelength and/or intensity) of a transmitted or reflected portion of the input light provided to (e.g., coupled into) the optical fiber can be changed by strain applied to the FBG section. In addition to being sensitive to strain, the spectral response is sensitive to temperature.

This means that fiber Bragg gratings can be used as sensing elements in optical fiber sensors. The sensitivity of the Bragg wavelength to an applied strain (S) and a change in temperature (ΔT) is approximately given by:

$$[ \frac{{Δλ}_{B}}{λ} ] = {C}_{S} S + {C}_{T} Δ T ,$$

where C_{S} is the coefficient of strain, and C_{T} is the coefficient of temperature.

Therefore, FBGs can be used as sensing elements in optical fiber sensors for monitoring and detecting certain measurands (e.g., particles, chemicals, and energy). In a FBG sensor, a change in (e.g., presence/absence of) the measurand causes a shift in the Bragg wavelength and/or a change in an intensity of the detected light portion (transmitted or reflected). FBGs can thus be used as direct sensing elements for strain and temperature.

The FBG sensor can also be used as transduction elements, converting the output of another sensor, which generates a strain or temperature change from the measurand. For example, FBG gas sensors use an absorbent coating, which in the presence of a gas expands generating a strain, which is measurable by the grating. Technically, the absorbent material is the sensing element, converting the amount of gas to a strain. The FBG then transduces the strain to a change in the Bragg wavelength.

FBGs can find uses in instrumentation applications such as downhole sensors in oil and gas wells for measurement of the effects of external pressure, temperature, seismic vibrations and inline flow measurement. As such they offer a significant advantage over traditional electronic gauges used for these applications in that they are less sensitive to vibration or heat and consequently are far more reliable.

In one aspect, an FBG is a small length of single mode fiber that has been specially treated and “etched” in a very specific manner using a high power laser. Depending on how the FBG has been processed and installed, it can be a pass or reject filter, for instance, it can be set to only pass one frequency of light or reject one frequency while passing all others.

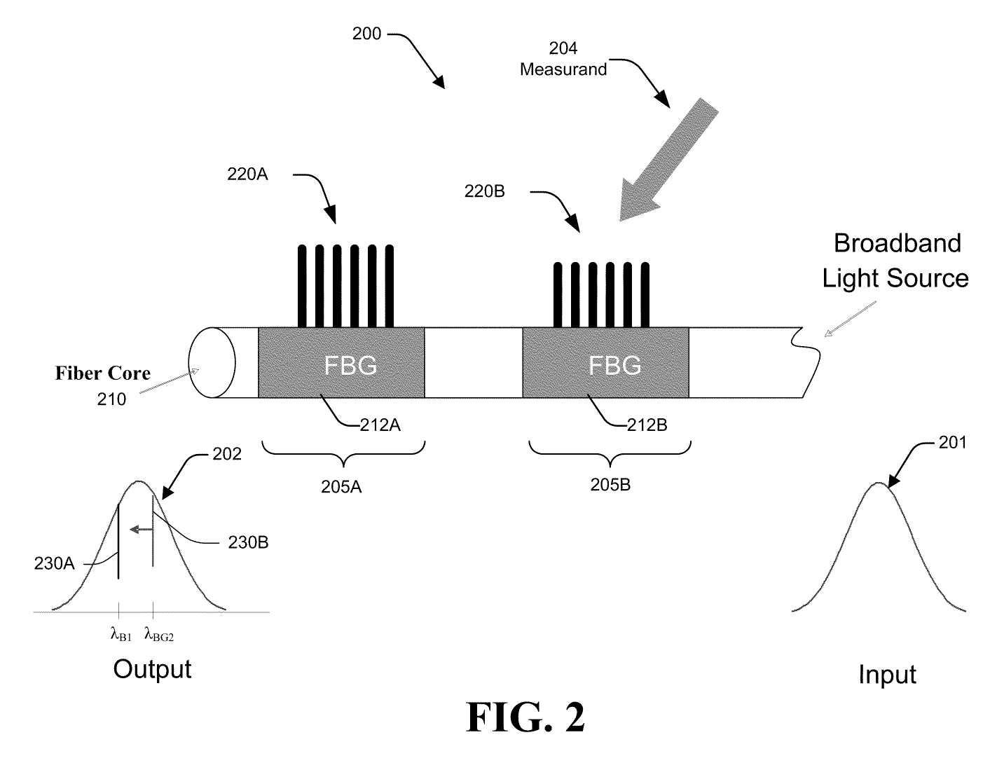

FIG. 2 is a diagram depicting an exemplary FBG sensor 200 having carbon nanotubes (CNTs) as sensing elements (hereinafter the “CNT-bearing FBG sensor”) according to certain aspects of the present disclosure. The exemplary CNT-bearing FBG sensor 200 includes an optical fiber 210 having first and second FBG sections 212A, 212B constructed therein, and carbon nanotubes (CNTs) 220A, 220B grown on and surrounding at least portions of the first and second FBG sections 212A, 212B. In the illustrated embodiment, the optical fiber 210 is a fiber core. In other embodiments, the optical fiber 210 can also include an outer cladding surrounding the fiber core, except at the FBG sections 212A, 212B where the CNTs 220A, 220B are located. Each pair of FBG section 212A, 212B and its surrounding CNTs 220A, 220B will be hereinafter referred to as a “CNT-infused FBG” 205A, 205B.

In certain embodiments, the fiber core 210 includes a glass fiber material. In other embodiments, the optical fiber 220 includes a polymer (e.g., plastic) fiber material. Each of the first and second FBG sections 212A, 212B can be constructed by “inscribing” or “writing” systematic (periodic or aperiodic) variation of refractive index to the fiber core 210 using an intense ultraviolet (UV) radiation source such as a UV laser. Processes used to inscribe such systematic variation in the fiber core include interference, masking, and point-by-point processes. The choice of a particular process employed depends on the type of grating to be manufactured. In some embodiments, the FBG section is constructed in germanium-doped silica fiber. The germanium-doped fiber is photosensitive, and the refractive index of the core changes with exposure to UV light, the amount of the change being a function of the intensity and duration of the exposure.

In an FBG section, a particular construction (e.g., a spacing or spacings between regions of high and low refractive indices) determines a spectral response (e.g., a Bragg wavelength) of the FBG section. A spectral response may comprise a general shape (e.g., height, width) of the spectrum of an output light 202 and/or one or more “rejects” 230A, 230B at one or more Bragg wavelengths in the spectrum. A “reject” 230A may be a notch (having a certain magnitude) in the spectrum of an output light.

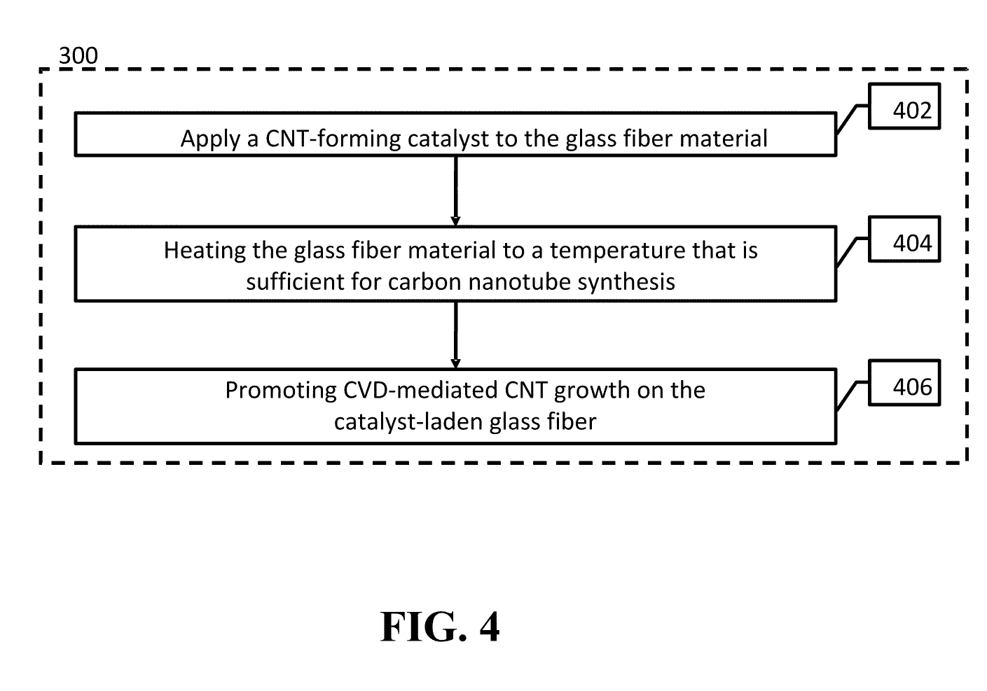

In certain embodiments, the first and second FBG sections 212A, 212B are of the same construction and hence have the same spectral response. In other embodiments, the first and second FBG sections 212A, 212B are of different constructions and hence have different spectral responses (e.g., different response bands and/or Bragg wavelengths). One skilled in the art will recognize that additional FBG sections can be included that have the same or different spectral responses as FBG sections 212A and 212B. Thus, there can be, for example, three, four, five, six, up to 100's of FBG sections. CNTs (e.g., 220A, 220B) can be grown on different types of optical fiber by a multitude of different processes. One exemplary process for growing CNTs on a glass fiber core is described below with respect to FIG. 4. The presence of the CNTs affects the spectral response of the FBG section underlying the CNTs, e.g., by applying a strain or inducing a change in temperature and/or refractive index.

In certain embodiments, the CNTs 220A, 220B comprise a plurality of carbon nanotubes each of which is grown in a radial direction of the fiber core 110 such that an axis of each nanotube thus grown is substantially along the radial direction. The height of such a nanotube can range, for example, from 3 to 150 μm.

A set of CNTs can surround or cover all or portions of the corresponding FBG section. For instance, the CNTs 220A may surround or cover all or portions of the FBG section 212A, and/or the CNTs 220B may surround or cover all or only portions of the FBG section 212B. In one example, the CNTs 220A cover the entire outer surface of the FBG section 212A in both length (e.g., axial) and circumferential (e.g., around the fiber core) directions. In another example, the CNTs 220A cover only a certain portion of the FBG section 212A along the length direction while covering the entire outer surface of the FBG section 212A along the circumferential direction within the covered length portion. In yet another example, the CNTs 220A cover only a portion of the FBG section 212A along the circumferential direction. The portion partially covered along the circumferential direction can extend the entire length of the FBG section 212A or only a portion thereof (e.g., a middle portion of the FBG section 212A). Similar coverage possibilities exist for the CNTs 220B with respect to the FBG section 212B.

In certain embodiments, the CNTs 220A, 220B are grown to possess certain characteristics for efficiently absorbing a measurand 204 of interest, such as certain particles, chemicals, or radiated energy. Radiated energy can include sonar energy and electromagnetic energy impinging on the CNTs.

For absorbing particles, for example, the CNTs 220A, 220B can be grown to possess single-wall CNTs and multi-wall CNTs with functionalization utilizing groups such as carboxylic, amine, nitrates, and hydroxyl groups, which typically contain electron mobility. Particle absorption can cause changes in absorption or reflection of the entire electromagnetic spectrum. For absorbing chemicals, for example, the CNTs 220A, 220B can be grown to possess a particular functionality with the highest available affinity for a particular chemical. Chemical absorption can cause changes in absorption or reflection of the entire electromagnetic spectrum. The CNTs can expand, contract and oscillate in different modes upon absorbing chemicals, radiations, or energy and hence affecting the reflection characteristics of the FBGs.

After absorbing particles, chemicals, or energy, certain characteristics (e.g., strain or temperature) of the CNTs undergo a change. For example, when the CNTs absorb chemicals such as acetone, alcohols, hazardous gases, chemicals or biological warfare agent, the CNTs can experience a change in refractive index and/or strain. The changes in the CNTs, in turn, cause a change in the spectral response of the FBG section underlying the CNTs. As another example, when the CNTs absorb a form of radiated energy (e.g., RF or sonar wave), the absorbed energy causes a rise in temperature of the CNTs and of the underlying FBG section. The rise in temperate, in turn, causes a shift in the Bragg wavelength of the FBG section.

In one experimental embodiment, an input light from a 1510 nm laser source was provided to the fiber core. The input light was passed through the CNT-bearing sensor. The light interacts with the CNT-infused FBG, and the output light is received by the photo detector. The transmitted light was observed at 1516 nm or a 6 nm shift from the original wavelength. The FBG with CNTs was then subjected to acetone vapors. The transmitted light wavelength shifted by 3 nm and was observed at 1513 nm. As the acetone evaporated in a few seconds, the transmitted light wavelength returned to its original observed value of 1516 nm.

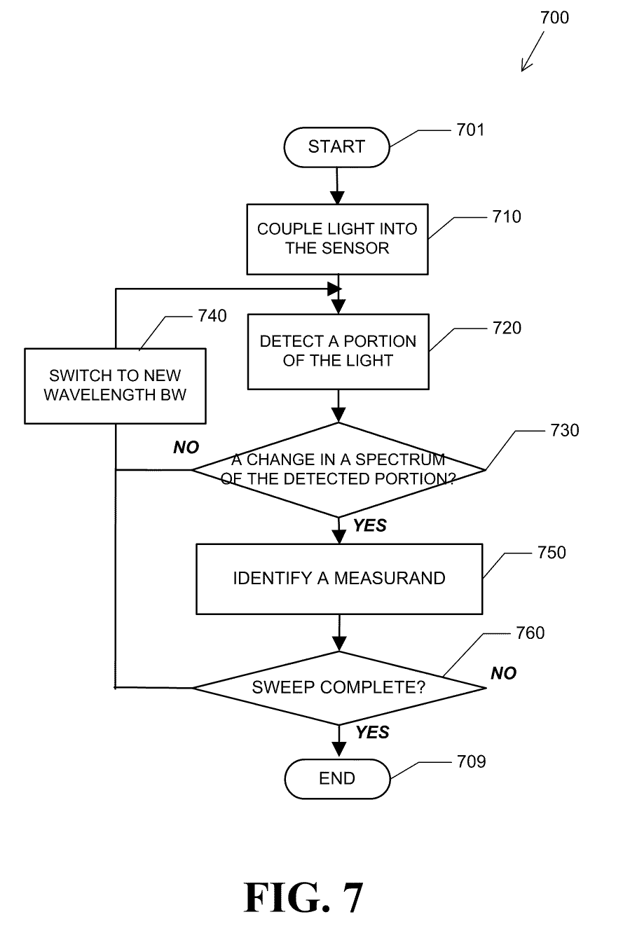

In operation, input light 201 from a light source (e.g., a laser, not shown), is provided to the fiber core 210. In the illustrated embodiment, the input light 201 is a broadband light having a spectrum or wavelength bandwidth encompassing a full range of wavelengths of interest. In alternative embodiments, however, the input light 201 is a relatively narrowband light having a spectrum or wavelength bandwidth narrower than a full range of wavelengths of interest. In those alternative embodiments, the spectrum or wavelength bandwidth of the input light 201 can be swept across the full range of wavelengths of interest as will be described in detail below with respect to FIG. 7.

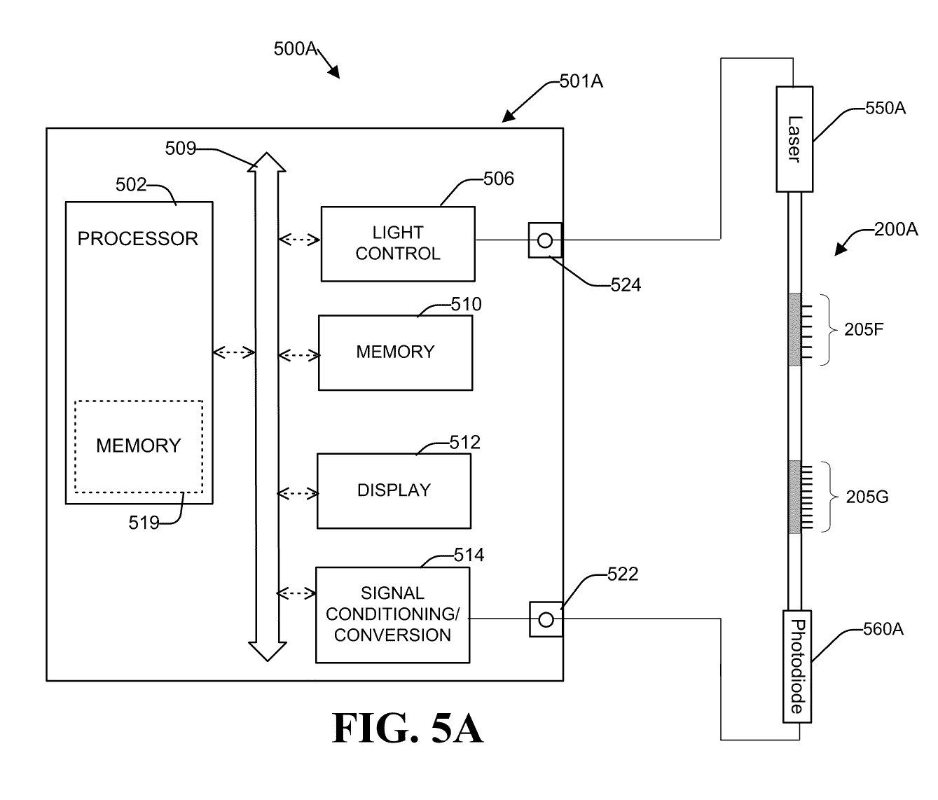

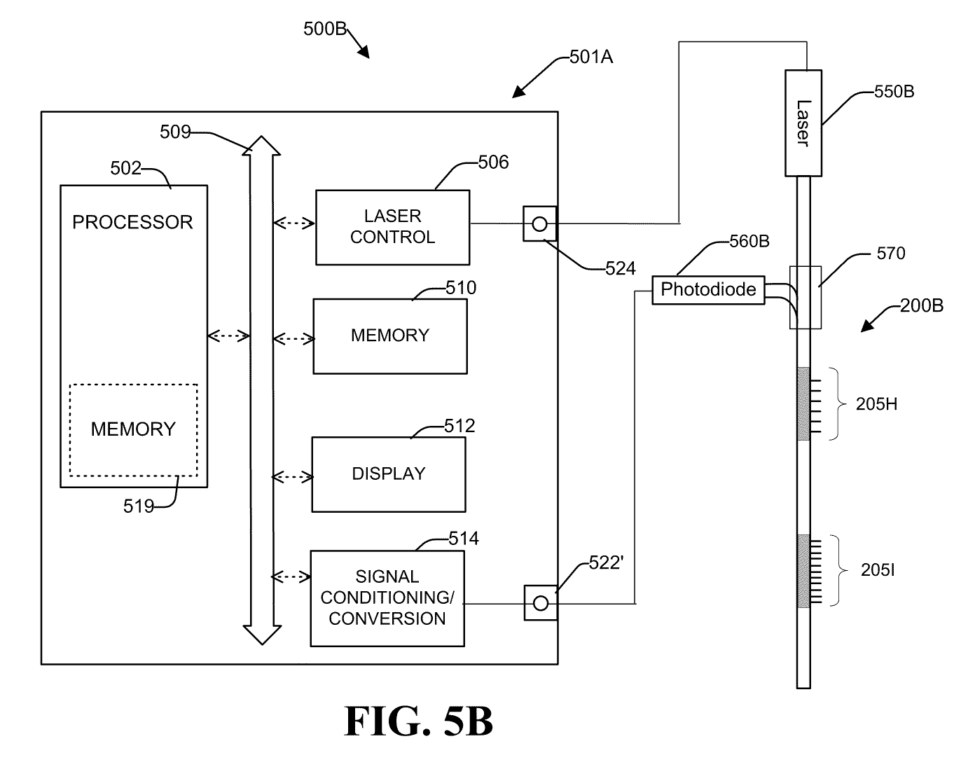

Returning to FIG. 2, as the input light 201 is passed through the CNT-bearing sensor 200, the light interacts (e.g., reflected and/or diffracted by) with the first and second CNT-infused FBGs 205A, 205B, and the output light 202 (which in the illustrated example corresponds to a transmitted portion of the input light 201) is received by a photodetector (shown in FIGS. 5A and 5B). In the illustrated example, the first and second FBG sections 212A, 212B have different constructions (e.g., different periodic spacings) and thus having correspondingly different first and second Bragg wavelengths 230A, 230B. Also in the illustrated example, an external measurand 204 is absorbed by the second CNTs 220B, but not by the first CNTs 220A. Hence, the second Bragg wavelength 230B, but not the first Bragg wavelength 230A, experiences a shift as indicated in the illustrated spectrum of the output light 202. By positioning the first and second CNT-infused FBGs 205A, 205B at different measurement locations (e.g., different rooms in a building) and by determining which of the Bragg wavelengths 230A, 230B has experienced a shift, the presence of certain measurand(s) (e.g., toxic gases) at the different locations can be independently determined.

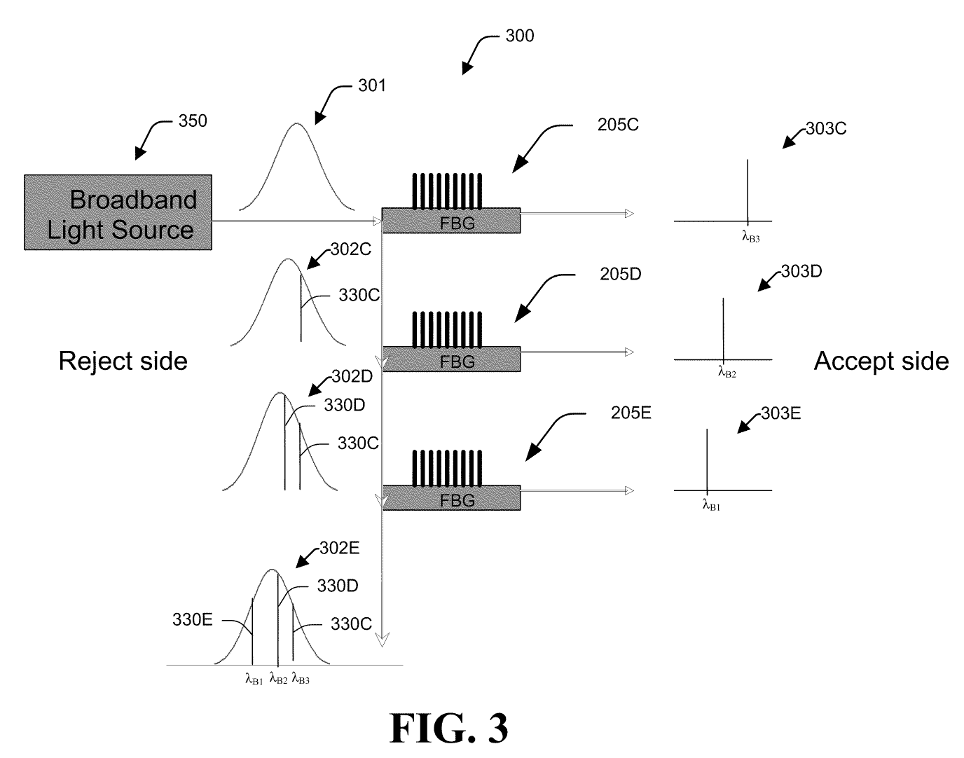

FIG. 3 is a diagram depicting an exemplary sensing system 300 comprising an FBG sensor having multiple CNT-infused FBGs 205C, 205D, 205E according to certain aspects of the present disclosure. The CNT-infused FBGs 205C, 205D, 205E can be used in series and/or in parallel, and the choice is dependent on the power of the laser source. The sensing system 300 includes a broadband light source 350 configured to provide input light 301 into a CNT-bearing sensor comprising a first CNT-infused FBG 205C, a second CNT-infused FBG 205D and a third CNT-infused FBG 205E. Transmitted portions of the input light 301 at the respective outputs of the first, second, and third CNT-infused FBGs 205C, 205D, 205E are shown on the transmission or “reject” side as first, second, and third output lights 302C, 302D, 302E, respectively. Reflected portions of the input light 301 at the inputs of the first, second, and third CNT-infused FBGs are shown on the reflection or “accept side” as first, second, and third output lights 303C, 303D, 303E, respectively. In certain embodiments, the first, second, and third CNT-infused FBGs 205C, 205D, 205E are connected in series along an optical fiber. In some of those embodiments, a photodetector (not shown) is connected at the output side of the optical fiber to detect the third light output 302C. In other embodiments, a photodetector (not shown) is coupled to the input side of the optical fiber to receive a reflected light comprising the combination of the first, second, and third output lights 303C, 303D, 303E. In yet other embodiments, multiple photodetectors (not shown) can be employed to independently receive the reflected first, second, and third output lights 303C, 303D, 303E. This can be achieved by, for example, coupling each of the multiple photodetectors at an input side each of the first, second, and third CNT-infused FBGs 205C, 205D, 205E.

FIG. 4 depicts a flowchart illustrating an exemplary process 400 for producing CNT-infused glass fiber material, whereby CNT-infused FBGs (e.g., 205A, 205B of FIGS. 2 and 205C, 205D, 205E of FIG. 3) can be fabricated according to certain aspects of the present disclosure. Process 400 includes at least the operations of:
402: Applying a CNT-forming catalyst to the glass fiber material,
404: Heating the glass fiber material to a temperature that is sufficient for carbon nanotube synthesis, and
406: Promoting CVD-mediated CNT growth on the catalyst-laden glass fiber.

To infuse carbon nanotubes into a glass fiber material, the carbon nanotubes are synthesized directly on the glass fiber material. In the illustrative embodiment, this is accomplished by first disposing nanotube-forming catalyst on the glass fiber, as per operation 402.

Preceding catalyst deposition, the glass fiber material can be optionally treated with plasma to prepare the surface to accept the catalyst. For example, a plasma treated glass fiber material can provide a roughened glass fiber surface in which the CNT-forming catalyst can be deposited. In some embodiments, plasma can be also used to “clean” the fiber surface. The plasma process for “roughing” the surface of the glass fiber materials thus facilitates catalyst deposition. The roughness is typically on the scale of nanometers. In the plasma treatment process craters or depressions are formed that are nanometers deep and nanometers in diameter. Such surface modification can be achieved using a plasma of any one or more of a variety of different gases, including, without limitation, argon, helium, oxygen, ammonia, nitrogen and hydrogen.

As described further below and in conjunction with FIG. 4, the catalyst is prepared as a liquid solution that contains CNT-forming catalyst that comprises transition metal nanoparticles. The diameters of the synthesized nanotubes are related to the size of the metal particles as described above.

With reference to the illustrative embodiment of FIG. 4, carbon nanotube synthesis is shown based on a chemical vapor deposition (CVD) process and occurs at elevated temperatures. The specific temperature is a function of catalyst choice, but will typically be in a range of about 500 to 1000° C. Accordingly, operation 404 involves heating the glass fiber material to a temperature in the aforementioned range to support carbon nanotube synthesis.

In operation 406, CVD-promoted nanotube growth on the catalyst-laden glass fiber material is then performed. The CVD process can be promoted by, for example, a carbon-containing feedstock gas such as acetylene, ethylene, and/or ethanol. The CNT synthesis processes generally use an inert gas (e.g., nitrogen, argon, helium) as a primary carrier gas. The carbon feedstock is provided in a range from greater than 0% to about 15% of the total mixture. A substantially inert environment for CVD growth is prepared by removal of moisture and oxygen from the growth chamber.

In the CNT synthesis process, CNTs grow at the sites of a CNT-forming transition metal nanoparticle catalyst. The presence of the strong plasma-creating electric field can be optionally employed to affect nanotube growth. That is, the growth tends to follow the direction of the electric field. By properly adjusting the geometry of the plasma spray and electric field, vertically-aligned CNTs (i.e., perpendicular to the glass fiber material) can be synthesized. Under certain conditions, even in the absence of a plasma, closely-spaced nanotubes will maintain a vertical growth direction resulting in a dense array of CNTs resembling a carpet or forest.

The operation of disposing a catalyst on the glass fiber material can be accomplished by spraying or dip coating a solution or by gas phase deposition via, for example, a plasma process. Thus, in some embodiments, after forming a solution of a catalyst in a solvent, catalyst can be applied by spraying or dip coating the glass fiber material with the solution, or combinations of spraying and dip coating. Either technique, used alone or in combination, can be employed once, twice, thrice, four times, up to any number of times to provide a glass fiber material that is sufficiently uniformly coated with CNT-forming catalyst. When dip coating is employed, for example, a glass fiber material can be placed in a first dip bath for a first residence time in the first dip bath. When employing a second dip bath, the glass fiber material can be placed in the second dip bath for a second residence time. For example, glass fiber materials can be subjected to a solution of CNT-forming catalyst for about 4 seconds to about 90 seconds depending on the dip configuration and linespeed. Employing spraying or dip coating processes, a glass fiber material with a surface density of catalyst of less than about 5% surface coverage to as high as about 80% coverage, in which the CNT-forming catalyst nanoparticles are nearly monolayer. In some embodiments, the process of coating the CNT-forming catalyst on the glass fiber material produces no more than a monolayer. For example, CNT growth on a stack of CNT-forming catalyst can erode the degree of infusion of the CNT to the glass fiber material. In other embodiments, the transition metal catalyst can be deposited on the glass fiber material using evaporation techniques, electrolytic deposition techniques, and other processes known to those skilled in the art, such as addition of the transition metal catalyst to a plasma feedstock gas as a metal organic, metal salt or other composition promoting gas phase transport.

The catalyst solution employed can be a transition metal nanoparticle which can be any d-block transition metal. In addition, the nanoparticles can include alloys and non-alloy mixtures of d-block metals in elemental form or in salt form, and mixtures thereof. Such salt forms include, without limitation, oxides, carbides, and nitrides. Non-limiting exemplary d-block transition metal NPs include Ni, Fe, Co, Mo, Cu, Pt, Au, and Ag and salts thereof and mixtures thereof. In some embodiments, such CNT-forming catalysts are disposed on the glass fiber by applying or infusing a CNT-forming catalyst directly to the glass fiber material. Many of these transition metal catalysts are readily commercially available from a variety of suppliers, including, for example, Ferrotec Corporation (Bedford, N.H.).

Catalyst solutions used for applying the CNT-forming catalyst to the glass fiber material can be in any common solvent that allows the CNT-forming catalyst to be uniformly dispersed throughout. Such solvents can include, without limitation, water, acetone, hexane, isopropyl alcohol, toluene, ethanol, methanol, tetrahydrofuran (THF), cyclohexane or any other solvent with controlled polarity to create an appropriate dispersion of the CNT-forming catalyst nanoparticles. Concentrations of CNT-forming catalyst can be in a range from about 1:1 to 1:10000 catalyst to solvent.

In some embodiments, after applying the CNT-forming catalyst to the glass fiber material, the glass fiber material can be heated to a softening temperature. This can aid embedding the CNT-forming catalyst into the surface of the glass fiber material and can encourage seeded growth without catalyst “floating.” In some embodiments heating of the glass fiber material after disposing the catalyst on the glass fiber material can be at a temperature that is between about 500° C. and 1000° C.

The step of synthesizing carbon nanotubes can include numerous techniques for forming carbon nanotubes, including those disclosed in co-pending U.S. Patent Application Publication No. US 2004/0245088 which is incorporated herein by reference. The CNTs grown on fibers of the subject technology can be accomplished by techniques known in the art including, without limitation, micro-cavity, thermal or plasma-enhanced CVD techniques, laser ablation, arc discharge, and high pressure carbon monoxide (HiPCO). In some embodiments, acetylene gas is ionized to create a jet of cold carbon plasma for CNT synthesis. The plasma is directed toward the catalyst-bearing glass fiber material. Thus, in some embodiments, synthesizing CNTs on a glass fiber material includes (a) forming a carbon plasma; and (b) directing the carbon plasma onto the catalyst disposed on the glass fiber material. The diameters of the CNTs that are grown are dictated by the size of the CNT-forming catalyst as described above. In some embodiments, the sized fiber substrate is heated to between about 550° C. and about 800° C. to facilitate CNT synthesis. To initiate the growth of CNTs, two gases are bled into the reactor: a process gas such as argon, helium, or nitrogen, and a carbon-containing gas, such as acetylene, ethylene, ethanol or methane. CNTs grow at the sites of the CNT-forming catalyst.

In some embodiments, the CVD growth is plasma-enhanced. A plasma can be generated by providing an electric field during the growth process. CNTs grown under these conditions can follow the direction of the electric field. Thus, by adjusting the geometry of the reactor vertically aligned carbon nanotubes can be grown radially about a cylindrical fiber. In some embodiments, a plasma is not required for radial growth about the fiber. For glass fiber materials that have distinct sides such as tapes, mats, fabrics, plies, and the like, catalyst can be disposed on one or both sides and correspondingly, CNTs can be grown on one or both sides as well.

As described above, CNT-synthesis is performed at a rate sufficient to provide a continuous process for functionalizing spoolable glass fiber materials. Numerous apparatus configurations facilitate such continuous synthesis as exemplified below.

In some embodiments, CNT-infused glass fiber materials can be constructed in an “all plasma” process. In such embodiments, glass fiber materials pass through numerous plasma-mediated steps to form the final CNT-infused product. The first of the plasma processes, can include a step of fiber surface modification. This is a plasma process for “roughing” the surface of the glass fiber material to facilitate catalyst deposition, as described above. As described above, surface modification can be achieved using a plasma of any one or more of a variety of different gases, including, without limitation, argon, helium, oxygen, ammonia, hydrogen, and nitrogen.

After surface modification, the glass fiber material proceeds to catalyst application. This is a plasma process for depositing the CNT-forming catalyst on the fibers. The CNT-forming catalyst is typically a transition metal as described above. The transition metal catalyst can be added to a plasma feedstock gas as a precursor in the form of a ferrofluid, a metal organic, metal salt or other composition for promoting gas phase transport. The catalyst can be applied at room temperature in the ambient environment with neither vacuum nor an inert atmosphere being required. In some embodiments, the glass fiber material is cooled prior to catalyst application.

Continuing the all-plasma process, carbon nanotube synthesis occurs in a CNT-growth reactor. This can be achieved through the use of plasma-enhanced chemical vapor deposition, wherein carbon plasma is sprayed onto the catalyst-laden fibers. Since carbon nanotube growth occurs at elevated temperatures (typically in a range of about 500 to 1000° C. depending on the catalyst), the catalyst-laden fibers can be heated prior to exposing to the carbon plasma. For the infusion process, the glass fiber material can be optionally heated until it softens. After heating, the glass fiber material is ready to receive the carbon plasma. The carbon plasma is generated, for example, by passing a carbon containing gas such as acetylene, ethylene, ethanol, and the like, through an electric field that is capable of ionizing the gas. This cold carbon plasma is directed, via spray nozzles, to the glass fiber material. The glass fiber material can be in close proximity to the spray nozzles, such as within about 1 centimeter of the spray nozzles, to receive the plasma. In some embodiments, heaters are disposed above the glass fiber material at the plasma sprayers to maintain the elevated temperature of the glass fiber material.

Another configuration for continuous carbon nanotube synthesis involves a special rectangular reactor for the synthesis and growth of carbon nanotubes directly on glass fiber materials. The reactor can be designed for use in a continuous in-line process for producing carbon-nanotube bearing fibers. In some embodiments, CNTs are grown via a chemical vapor deposition (CVD) process at atmospheric pressure and at elevated temperature in the range of about 550° C. to about 800° C. in a multi-zone reactor. The fact that the synthesis occurs at atmospheric pressure is one factor that facilitates the incorporation of the reactor into a continuous processing line for CNT-on-fiber synthesis. Another advantage consistent with in-line continuous processing using such a zone reactor is that CNT growth occurs in seconds, as opposed to minutes (or longer) as in other procedures and apparatus configurations typical in the art.

FIG. 5A is a schematic block diagram of an exemplary transmission (reject)-type sensing system 500A configured to monitor and detect a measurand based on a transmitted portion of the input light (hereinafter the “transmitted light portion”) according to certain aspects of the present disclosure. The sensing system 500A includes a control/analysis unit 501A, a light source 550A (e.g., a laser), a CNT-bearing FBG sensor 200A, and a photodetector 560A (e.g., photodiodes). The control/analysis unit 501A includes a processor 502, which can be a desktop computer or a laptop computer. The processor 502 is capable of communication with a laser control module 506 through a bus 509 or other structures or devices. It should be understood that communication means other than buses can be utilized with the disclosed configurations.

The processor 502 may include a general-purpose processor or a specific-purpose processor for executing instructions and may further include an internal memory 519, such as a volatile or non-volatile memory, for storing data and/or instructions for software programs. The instructions, which may be stored in a memory 510 and/or 519, may be executed by the processor 502 to control and manage access to the various networks, as well as provide other communication and processing functions. The instructions may also include instructions executed by the processor 502 for various user interface devices, such as a display 512 and a keyboard or keypad (not shown).

The processor 502 may be implemented using software, hardware, or a combination of both. By way of example, the processor 502 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium (e.g., 519, 510) that stores software for control, analysis and other processing functions can be one or more machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media may include storage integrated into a processing system, such as might be the case with an ASIC. Machine-readable media (e.g., 510) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. In addition, machine-readable media may include a transmission line or a carrier wave that encodes a data signal. Those skilled in the art will recognize how best to implement the described functionality for the processing system 502. According to one aspect of the disclosure, a machine-readable medium is a computer-readable medium or computer-readable storage medium encoded or stored with instructions and is a computing element, which defines structural and functional interrelationships between the instructions and the rest of the system, which permit the instructions' functionality to be realized. Instructions can be, for example, a computer program including code.

The light control module 506 may be a hardware module or a software module or a combination of both (e.g., a firmware) and may contain hardware components and/or control programs that are configured to control the light source 550A (e.g., laser), which can be broadband or narrowband. The light control module 506 is configured to send one or more control signals to the light source 550A via an output port 524, thereby causing the light source 702 to provide light (201 of FIG. 2) into the CNT-bearing FBG sensor 200A. The light can be broadband or narrowband. In certain embodiments, the light control module 506 is part of and resides in the light source 550A.

In the illustrated example of FIG. 5A, the CNT-bearing FBG sensor 200A includes first and second CNT-infused FBGs 205F, 205G. The light provided into the sensor 200A from the light source 550A interacts with the FBGs 205F, 205G which are exposed to one or more measurands. The presence of the one or more measurands causes a certain change in the spectrum of the transmitted light portion. The change can include a shift in a Bragg wavelength and/or an increase or decrease in the peak or integrated intensity of the transmitted light portion.

In the illustrated transmission (reject)-type sensing system 500A, the photodetector 560A (e.g., photodiodes) is disposed at an output side (e.g., end of the optical fiber) of the CNT-bearing FBG sensor 200A. The transmitted light portion is detected by the photodetector 560A, which converts the detected transmitted light portion into an electrical signal. The electrical signal output of the photodetector 560A is received by a signal conditioning/conversion module 514 via an input port 522. The signal conditioning/conversion module 514 conditions (e.g., filters and amplifies) the electrical signal and converts (e.g., digitizes) it into a digital representation. The digital representation is then received and processed (e.g., analyzed) by the processor 702 to determine change(s) in the spectrum of the transmitted light portion and identify one or more measurands that have caused the change(s).

FIG. 5B is a schematic block diagram of an exemplary reflection (accept)-type sensing system 500B that is configured to monitor and detect a measurand based on a reflected portion of the input light (hereinafter the “reflected light portion”) according to certain aspects of the present disclosure. The sensing system 500B includes a control/analysis unit 501B, a light source 550B (e.g., a laser), a CNT-bearing FBG sensor 200B, and a photodetector 560B (e.g., photodiodes). The control/analysis unit 501B, the light source 200B, and the sensor 200B of the exemplary sensing system 500B of FIG. 5B are substantially similar to those of the exemplary sensing system 500A of FIG. 5A and are not separately described here.

One difference between the transmission-type sensing system 500A of FIG. 5A and the reflection-type sensing system 500B of FIG. 5B relates to whether the transmitted light portion or the reflected light portions is received and analyzed. While the photodetector 560A is disposed at the output side of the sensor 200A to receive the transmitted light portion in the transmission-type sensing system 500A, the photodetector 560B is disposed at an input side of the sensor 200B to receive the reflected light portion in the reflection-type sensing system 500B. In the illustrated example of FIG. 5B, the reflected light portion is received by the photodetector 560B via a directional coupler 570. The photodetector 560B converts the detected reflected light portion into an electrical signal. The electrical signal output by the photodetector 560B is received by a signal conditioning/conversion module 514 via an input port 522′. The signal conditioning/conversion module 514 conditions (e.g., filters and amplifies) the electrical signal and converts (e.g., digitizes) the conditioned signal into a digital representation. The digital representation is then received and processed (e.g., analyzed) by the processor 702 to determine change(s) in the spectrum of the reflected light portion and identify one or more measurands that have caused the change(s).

It shall be appreciated that the illustrated embodiments of FIGS. 5A and 5B are exemplary only, and a multitude of changes including modifications, additions, deletions can be made to the embodiments without departing from the scope of the present disclosure. For example, a hybrid sensing system in which both the transmitted light portion and the reflected light portions are received and analyzed may be employed. A hybrid sensing system can include a first photodetector disposed at the output side of a sensor to receive the transmitted light portion, and a second photodetector disposed at an input side of the sensor to receive the reflected light portion via a directional coupler. An electrical signal output by the first photodetector can be received by a signal conditioning/conversion module (e.g., 514) via a first input port (e.g., 522), and an electrical signal output by the second photodetector can be received by the signal conditioning/conversion module (e.g., 514) via a second input port (e.g., 522′).

In certain embodiments, a CNT-bearing FBG sensor (e.g., 200A, 200B) is calibrated at least once before the sensor is used for monitoring and detecting anticipated measurands. In some embodiments, the sensor is calibrated periodically. The calibration procedure involves passing light through the sensor without exposing the CNT-infused FBGs (e.g., 205F, 205G, 205H, 205I) to anticipated measurands, and receiving and analyzing one of reflected and transmitted light portions to establish an original finger print, which can include one or more reference Bragg wavelengths and/or a peak or integrated light intensity.

Subsequently, the CNT-infused FBGs (e.g., 205F, 205G, 205H, 205I) are exposed to various anticipated measurands (e.g., particles, chemicals, energy). For example, after an exposure to a particular anticipated measurand, light is again provided to the sensor, and a transmitted/reflected light portion is received by a photodetector (e.g., 560A, 560B). The signal generated by the photodetector reveals a different fingerprint (e.g., a shifted Bragg wavelength and/or a different peak/integrated intensity), due to the different state of the CNTs. The difference between the original fingerprint and the new fingerprint resulting from the absorbed measurand is then quantified.

This process is repeated for a variety of different anticipated measurands (e.g., contaminants, agents, environmental conditions) that the sensor is intended to monitor and detect. In this way, the behavior of the CNT-bearing FBG sensor is characterized for all anticipated measurands. A look-up table of the differences for all monitored conditions can be created and stored in a computer-readable memory (e.g., 519, 510). In some embodiments, in addition to or in lieu of the look-up table of the differences, an entire spectrum of the transmitted and/or reflected light portion is stored in a memory for use during a monitoring and detecting process.

Once calibrated, the CNT-bearing FBG sensor can then be deployed and periodic readings taken by passing a laser light into the sensor and obtaining the updated fingerprint. If a change is observed that matches a previously established change listed in the look-up table, then an alert can be issued. In addition to using a frequency/wavelength based fingerprint, the sensor could be configured to measure attenuation of one or more frequencies or phase shift, using appropriate equipment (e.g., a Mach Zehnder interferometer for determining phase shift).

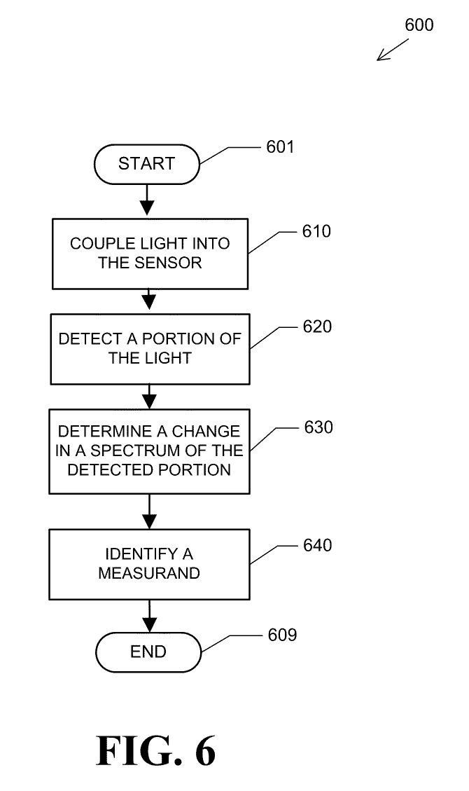

FIG. 6 is a flowchart illustrating an exemplary process 600 for monitoring and detecting one or more measurands by the use of a CNT-bearing FBG sensor according to certain aspects of the present disclosure. For ease of illustration, without any intent to limit the scope of the present disclosure in any way, the process 600 will be described with reference to exemplary embodiments of FIGS. 2, 3, 5A, and 5B. The process 600 begins at start state 601 and proceeds to operation 610 in which input light from a light source (e.g., 550A, 550B) is provided to the CNT-bearing FBG sensor (e.g., 200A, 200B) while the CNTs in the CNT-infused FBGs (e.g., 205F, 205G, 205H, 205I) are exposed to one or more measurands.

In certain embodiments, the input light is a broadband light having a spectrum that encompasses a full range of wavelengths of interest. Taking the example of the CNT-bearing FBG sensor 200 of FIG. 2 which includes the first CNT-infused FBG 205A having the first Bragg wavelength (λ_{B1}) and the second FBG 205A having the second Bragg wavelength (λ_{B2}), the broadband input light 201 has a spectrum wide enough to encompass a full response range of interest for the sensing system including various Bragg wavelengths (λ_{B1}, λ_{B2}) associated with the CNT-infused FBGs 205A, 205B and any variations in the Bragg wavelengths. For example, assume that the first and second Bragg wavelengths (λ_{B1}, λ_{B2}) are, respectively, 1,250 nm and 1,400 nm, and also that the first Bragg wavelength is known to shift to 1,200 nm when the first CNT-infused FBG 205A is exposed to a first measurand (e.g., a chemical of interest), and the second Bragg wavelength is known to shift to 1,320 nm when the second CNT-infused FBG 205B is exposed to a second measurand (e.g., the same chemical of interest at a same location, or a different chemical or the same or different location). Then, the spectrum or wavelength bandwidth (e.g., FWHM) of the input light 201 is at least 200 nm wide to cover the 1,200-1,400 nm response range for the sensing system.

The process 600 proceeds to operation 620 in which a portion of the light provided into the CNT-bearing FBG sensor is detected. In the sensing system 500A of FIG. 5A, the detected light portion is a transmitted portion of the light provided to the CNT-bearing FBG sensor. In the sensing system 500B of FIG. 5B, the detected light portion is a reflected portion of the light provided to the CNT-bearing FBG sensor.

The process 600 proceeds to operation 630 in which a change in a spectrum of the detected light portion is determined by a processor (e.g., 502). In certain embodiments, the operation 630 includes obtaining a spectrum of a corresponding one of the transmitted light portion and the reflection light portion. Taking the example of FIG. 3, the spectrum of the output light 302E (a transmitted light portion) can be analyzed to determine a possible shift in any of the Bragg wavelengths (e.g., λ_{B1}, λ_{B2}, and λ_{B3}) by comparing the Bragg wavelengths to reference Bragg wavelengths stored in a look-up table, for example. Alternatively, one or more of the reflected light portions 303C, 303D, 303E may be analyzed for the same purpose. Alternatively or additionally, the operation 630 may include comparing the spectrum of the detected light portion to a template or reference spectrum obtained and stored during a calibration procedure for matching signatures or features relating to certain measurands. Alternatively or additionally, the operation 630 may include determining a change in peak or integrated intensity of the detected light portion.

The process 600 then proceeds to operation 640 in which a measurand (e.g., particles, chemicals, or energy) that has caused the change is identified by the processor. In certain embodiments, the identification operation 640 involves identifying a measurand that is found to cause the determined change during a previous calibration procedure. For example, assume that the change in the spectrum of the detected light portion determined at the operation 630 is a negative 125 nm shift in the second Bragg wavelength 203B (FIG. 2). A processor can compare the determined Bragg wavelength shift to a list of previously established Bragg wavelength shifts and identify a measurand (e.g., a biomolecule) that is known to cause the particular Bragg wavelength to shift. After measurands corresponding to different changes determined at the operation 630 are identified, the process 600 ends at state 609.

In certain alternative aspects, instead of utilizing a broadband light discussed above with respect to the process 600, a narrowband light having a relatively narrow wavelength bandwidth or spectrum is utilized, and the spectrum or wavelength bandwidth of the light is scanned or swept across a full response range of interest for monitoring and detecting one or more anticipated measurands in one or more locations. FIG. 7 is a flowchart illustrating an exemplary process 700 for monitoring and detecting one or more measurands (e.g., particles, chemicals and energy) by the use of a CNT-bearing FBG sensor according to such alternative aspects of the present disclosure. It is assumed that the CNT-bearing FBG sensor has been characterized or calibrated in the manner described above. As with the process 600 of FIG. 6, for ease of illustration, without any intent to limit the scope of the present disclosure in any way, the process 700 will be described with references to exemplary embodiments of FIGS. 2, 3, 5A, and 5B.

The process 700 begins at start state 701 and proceeds to operation 710 in which light (e.g., input light 201) from a light source (e.g., laser 550A, 550B) is provided to the CNT-bearing FBG sensor (e.g., 200A, 200B) while the CNTs in the CNT-infused FBGs (e.g., 205F, 205G, 205H, 205I) are exposed to one or more measurands. As discussed above, the light has a spectrum or wavelength bandwidth that is narrower than a full response range of interest. For example, the light can have a 50 nm bandwidth while the full response range of interest is 600 nm (e.g., from 1,200 nm to 1,800 nm). In some embodiments, the light source 550 (FIG. 5) is a tunable laser in which the wavelength of the output laser light can be tuned or swept across at least the full response range of interest. At this stage, the wavelength of the input light is set to an initial wavelength bandwidth (e.g., 1,200 nm-1,250 nm).

The process 700 proceeds to operation 720 in which a portion (reflected or transmitted) of the input light, if any, is detected by a photodetector (e.g., 560A, 560B), and then to decision state 730 in which it is determined whether a change has been absorbed in a spectrum of the detected light portion. In certain embodiments, the operation 730 involves calculating a shift in a Bragg wavelength from a reference Bragg wavelength. In other embodiments, the determination involves calculating a change (e.g., increase or decrease) in a peak or integrated intensity of the detected light portion. In some embodiments, the operation 730 involves steps of first determining whether any light portion has been detected at all with the input light set at the current wavelength bandwidth and, if there was a detected light portion, then focusing on (e.g., fine sweeping) the current wavelength bandwidth to obtain a spectrum of the detected light portion and determining a change (e.g., a shift in Bragg wavelength) in the spectrum. For example, in some embodiments, the CNT-bearing FBG sensor does not reflect a significant portion of the input light unless the CNTs are exposed to a measurand. In such cases, if the measurand were not present, there would not be any detected light portion. In that case, the decision state 730 determines that there is no change in the spectrum of the detected light portion (No).

If it is determined at the decision state 730 that there is no change in the spectrum of the detected light portion (No), either because there is no change in features (e.g., Bragg wavelength or intensity) of the spectrum of the detected light portion, or because no light portion (e.g., reflected portion) has been detected, the process 700 proceeds to operation 740 where the wavelength of the light is switched (e.g., increased) to a new wavelength bandwidth (e.g., 1,250-1,300 nm). Subsequently, another light measurement is taken with the new wavelength bandwidth at the operation 720, and another determination is made as to whether there is a change in the spectrum of a detected light portion, if any, with the new wavelength bandwidth at the decision state 730.

On the other hand, if it is determined at the decision state 730 that there is a change in the spectrum of the detected light portion in the current wavelength bandwidth (Yes), the process 700 proceeds to operation 750 in which a measurand that caused the change is identified. As discussed above with respect to the process 600 of FIG. 6, the identification process can involve comparing the change (e.g., a Bragg wavelength shift) to a list of changes associated with different measurands (e.g., chemicals or biomolecules) that have been established during a previous calibration procedure.

The process 700 then proceeds to operation 760 in which it is determined whether a sweep of a full response range of interest (e.g., 1,200-1,800 nm) has been completed. If the answer is No, the process 700 proceeds to the operation 740 where the wavelength of the light is switched to a new wavelength bandwidth, followed by the operation 720 and the decision state 730 as discussed above. On the other hand, if it is determined at the decision state 760 that the sweep has been completed (Yes), the process 700 ends at state 709.

Certain aspects of monitoring/detection processes (e.g., processes 600 and 700) of the present disclosure can be implemented in a processor (e.g., 502 of FIGS. 5A, B) and a memory (e.g., 519, 510). For instance, the operation 630 for determining a change in a spectrum of a transmitted or reflected light portion and the operation 640 for identifying a measurand that caused the change may be performed by the processor 502. By way of example, a determination (e.g., search) for one or more Bragg wavelengths (e.g., reject wavelengths) from a spectrum of the transmitted light portion, for instance, can be performed by the processor 702. In addition, an identification (e.g., an identification of the measurand at the operation 540, which can involve a comparison between the Bragg wavelength of the spectrum of the received light portion and a stored reference Bragg wavelength) may be also performed by the processor 502. Various coefficients and parameters (e.g., reference Bragg wavelengths and expected shifts thereof, and peak and/or reference integrated light intensity) associated with the above determination and identification and results thereof may be stored in the memory 510, 519. Some results, such as names of the detected measurands may be displayed on the display 512.

In certain aspects of the disclosure, FBGs are employed in optical communications systems such as notch filters, optical multiplexers and demultiplexers with an optical circulator, or Optical Add-Drop Multiplexers (OADMs).

It is understood that the specific order or hierarchy of steps in the processes disclosed is an illustration of exemplary approaches. Based upon design preferences, it is understood that the specific order or hierarchy of steps in the processes may be rearranged. Some of the steps may be performed simultaneously. The accompanying method claims present elements of the various steps in a sample order, and are not meant to be limited to the specific order or hierarchy presented.

In the previous description, numerous specific details are set forth, such as specific materials, structures, processes, etc., in order to provide a better understanding of the present disclosure. However, the present disclosure can be practiced without resorting to the details specifically set forth herein. In other instances, well-known processing techniques and instrumentalities have not been described in order not to unnecessarily obscure the present disclosure.

Examples of embodiments of the present disclosure and a few examples of its versatility are shown and described herein. It is to be understood that the present disclosure is capable of use in various other combinations and environments and is susceptible of changes and/or modifications within the scope of the inventive concept as expressed herein.

The foregoing description is provided to enable any person skilled in the art to practice the various embodiments described herein. While the foregoing embodiments have been particularly described with reference to the various figures and embodiments, it should be understood that these are for illustration purposes only and should not be taken as limiting the scope of the invention.

There may be many other ways to implement the invention. Various functions and elements described herein may be partitioned differently from those shown without departing from the spirit and scope of the invention. Various modifications to these embodiments will be readily apparent to those skilled in the art in view of the present disclosure, and generic principles defined herein may be applied to other embodiments. Thus, many changes and modifications may be made to the invention, by one having ordinary skill in the art in view of the present disclosure, without departing from the spirit and scope of the invention.

A reference to an element in the singular is not intended to mean “one and only one” unless specifically stated, but rather “one or more.” The term “some” refers to one or more. Pronouns in the masculine (e.g., his) include the feminine and neuter gender (e.g., her and its) and vice versa. Headings and subheadings, if any, are used for convenience only and do not limit the invention. Underlined and/or italicized headings and subheadings are used for convenience only, do not limit the invention, and are not referred to in connection with the interpretation of the description of the invention.

Terms such as “top,” “bottom,” “front,” “rear” and the like as used in this disclosure should be understood as referring to an arbitrary frame of reference, rather than to the ordinary gravitational frame of reference. Thus, a top surface, a bottom surface, a front surface, and a rear surface may extend upwardly, downwardly, diagonally, or horizontally in a gravitational frame of reference.

A phrase such as an “aspect” does not imply that such aspect is essential to the subject technology or that such aspect applies to all configurations of the subject technology. A disclosure relating to an aspect may apply to all configurations, or one or more configurations. A phrase such as an aspect may refer to one or more aspects and vice versa. A phrase such as an “embodiment” does not imply that such embodiment is essential to the subject technology or that such embodiment applies to all configurations of the subject technology. A disclosure relating to an embodiment may apply to all embodiments, or one or more embodiments. A phrase such an embodiment may refer to one or more embodiments and vice versa.

All structural and functional equivalents to the elements of the various embodiments of the invention described throughout this disclosure that are known or later come to be known to those of ordinary skill in the art are expressly incorporated herein by reference and intended to be encompassed by the invention. Moreover, nothing disclosed herein is intended to be dedicated to the public regardless of whether such disclosure is explicitly recited in the above description. No claim element is to be construed under the provisions of 35 U.S.C. §112, sixth paragraph, unless the element is expressly recited using the phrase “means for” or, in the case of a method claim, the element is recited using the phrase “step for.” Furthermore, to the extent that the term “include,” “have,” or the like is used in the description or the claims, such term is intended to be inclusive in a manner similar to the term “comprise” as “comprise” is interpreted when employed as a transitional word in a claim.

What is claimed is:

1. A sensor comprising:
an optical fiber having a radial direction and an axial direction, the optical fiber configured to transmit light along the axial direction and comprising a fiber Bragg grating (FBG) section; and
a plurality of carbon nanotubes (CNTs) surrounding at least a portion of the FBG section, the CNTs, when exposed to an external measurand, are configured to cause a change in a spectral response of the FBG section.

2. The sensor of claim 1, wherein an axis of each of the CNTs is substantially along the radial direction.

3. The sensor of claim 1, further comprising a photodetector configured to detect one of a transmitted portion and a reflected portion of the light.

4. The sensor of claim 1, further comprising a first photodetector configured to detect a transmitted portion of the light and a second photodetector configured to detect a reflected portion of the light.

5. The sensor of claim 1, wherein the external measurand comprises one of a particle, a chemical, and an energy absorbed by the CNTs.

6. The sensor of claim 1, wherein the change in the spectral response of the FBG section causes a change in an intensity of one of a transmitted portion and a reflected portion of the light.

7. The sensor of claim 1, wherein the change in the spectral response of the FBG section causes a shift in a wavelength of one of a transmitted portion and a reflected portion of the light.

8. The sensor of claim 7, wherein the wavelength is a Bragg wavelength of the FBG section.

9. The sensor of claim 1, wherein the optical fiber comprises multiple FBG sections and multiple sets of CNTs, each of the multiple sets of CNTs surrounding a corresponding one of the multiple FBG sections.

10. The sensor of claim 9, wherein at least some of the multiple FBG sections have different associated Bragg wavelengths.

11. A method of sensing an external measurand, the method comprising:
providing a sensor comprising an optical fiber, the optical fiber having at least one fiber Bragg grating (FBG) section and a plurality of carbon nanotubes (CNTs) surrounding at least a portion of the FBG section;
providing light to the sensor while the CNTs are exposed to one or more measurands;
determining a change in a spectrum of one of a transmitted portion and a reflected portion of the light; and
identifying a measurand that has caused the change.

12. The method of claim 11, wherein the light is a broadband light having a spectrum that encompasses a full response range of interest.

13. The method of claim 11, wherein the one or more measurands comprise one of a particle, a chemical, and an energy absorbed by the CNTs.

14. The method of claim 11, wherein the determining comprises comparing the spectrum to a reference spectrum.

15. The method of claim 11, wherein the determining comprises determining a shift in a Bragg wavelength in the spectrum.

16. The method of claim 11, wherein the determining comprises determining a change in intensity of the corresponding one of the transmitted portion and the reflected portion of the light.

17. A method of sensing an external measurand, the method comprising:
providing a sensor comprising an optical fiber, the optical fiber having a fiber Bragg grating (FBG) section and a plurality of carbon nanotubes (CNTs) surrounding at least a portion of the at least FBG;
providing light into the sensor while the CNTs are exposed to one or more measurands, the light having a wavelength bandwidth narrower than a full response range of interest;
sweeping the wavelength bandwidth of the light until a portion of the light is detected at a particular wavelength bandwidth;
determining a change in a spectrum of the detected portion; and
identifying a measurand that has caused the change.

18. The method of claim 17, wherein the detected portion comprises a reflected portion of the light.

19. The method of claim 17, wherein the one or more measurands comprises one of a particle, a chemical, and an energy absorbed by the CNTs.

20. The method of claim 19, wherein the identifying comprises comparing a Bragg wavelength to one or more known Bragg wavelengths associated with a plurality of external measurands.
